(19) United States
(12) Patent Application Publication
(10) Pub. No.: US 2009/0233437 A1
(43) Pub. Date: Sep. 17, 2009

(54) METHOD OF MANUFACTURING SEMICONDUCTOR DEVICE AND SEMICONDUCTOR DEVICE MANUFACTURED THEREBY

(76) Inventors: Seong-Ho Kim, Seoul (KR); Jun-Yong Noh, Yongin-Si (KR)

Correspondence Address: F. CHAU & ASSOCIATES, LLC, 130 WOODBURY ROAD, WOODBURY, NY, 11797, US

(21) Appl. No.: 12/402,976

(22) Filed: Mar. 12, 2009

(30) Foreign Application Priority Data
Mar. 14, 2008 (KR) 10-2008-0024009

(51) Int. Cl. H01L 21/768

(52) U.S. Cl. 438/618; 257/E21.575

(57) ABSTRACT

A method of manufacturing a semiconductor device and a semiconductor device manufactured thereby are provided. The method includes forming a molding layer on a substrate, forming support patterns spaced apart from each other on the molding layer, forming storage node electrodes penetrating the molding layer on sidewalls of the support patterns and wherein the storage node electrodes are supported by the support patterns. The method further includes removing the molding layer, forming a dielectric layer on the storage node electrodes, and forming a plate electrode on the dielectric layer.

### CROSS-REFERENCE TO RELATED APPLICATION

This application claims priority to Korean Patent Application No. 10-2008-0024009, filed on Mar. 14, 2008, the disclosure of which is hereby incorporated herein by reference in it's entirety.

### BACKGROUND

1. Technical Field

The present disclosure relates to a method of manufacturing a semiconductor device and to a semiconductor device manufactured thereby and, and more particularly, to a semiconductor device having a capacitor and to a method of manufacturing the semiconductor device.

2. Description of Related Art

Recently, as the degree of integration of semiconductor devices has been rapidly increased, the cross-sectional areas of cells of the semiconductor devices has thereby been significantly reduced. However, as the integration density of semiconductor memory devices such as a dynamic random-access memory (DRAM) including a capacitor increases, the area allocated to a unit cell may be reduced, thereby resulting in difficulties in obtaining sufficient capacitance in the capacitor of these devices required for these devices operating properly. For example, a capacitor in a semiconductor device such as a DRAM memory cell may function as a storage for electric charge to store information. Therefore, the capacitor requires sufficient capacitance and high reliability in long term repeated use.

### SUMMARY OF THE INVENTION

Exemplary embodiments of the present invention may provide a method of manufacturing a semiconductor device having storage node electrodes on which support patterns capable of preventing leaning of the storage node electrodes are disposed.

Exemplary embodiments of the present invention may also provide a semiconductor device having storage node electrodes on which support patterns capable of preventing leaning of the storage node electrodes are disposed.

In accordance with an exemplary embodiment of the present invention, a method of manufacturing a semiconductor device is provided. The method includes: forming a molding layer on a substrate, forming support patterns spaced apart from each other on the molding layer forming storage node electrodes penetrating the molding layer on both sidewalls of the support patterns and wherein the storage node electrodes are supported by the support patterns. The method further includes removing the molding layer, forming a dielectric layer on the storage node electrodes and forming a plate electrode on the dielectric layer.

The support patterns may be formed in parallel lines, and the storage node electrodes may be formed on the both sidewalls of the support patterns parallel to an extension direction of the support patterns and wherein the storage node electrodes are spaced at specific intervals in the extension direction. The storage node electrodes between the neighboring support patterns may be formed on the sidewalls of the neighboring support patterns.

The support patterns may be formed along rows and columns on the substrate at crossings between odd-numbered rows and odd-numbered columns and between even-numbered rows and even-numbered columns.

The method may further include, before the forming of the molding layer: forming an interlayer insulating layer having lower conductive lines on the substrate. Here, the support patterns may be formed to overlap the lower conductive lines. In this case, the lower conductive lines may be bit lines each formed to alternately and repeatedly have a passing part and a contact part electrically connected with the substrate and having a larger width than the passing part, and each of the support patterns may be formed to overlap the passing part.

The support patterns may be formed of a material layer having an etch selectivity with respect to the molding layer. In this case, the molding layer may be formed of a silicon oxide layer, and the support patterns may be formed of a silicon nitride layer.

The forming of the storage node electrodes may include: forming buried layer patterns on the molding layer exposed between the support patterns, patterning the buried layer patterns and the molding layer, and forming storage node holes to expose both sidewalls of the support patterns, forming a storage node layer to have a surface profile consistent with the substrate having the storage node holes, removing the storage node layer on upper surfaces of the buried layer patterns and the support patterns, and forming the storage node electrodes on the sidewalls of the support patterns.

The buried layer patterns may be formed of the same material layer as the molding layer, and the buried layer patterns may be removed while removing the molding layer.

The method may further include, before forming the molding layer: forming storage node plugs between the substrate and the molding layer. Here, the storage node holes may be formed to expose the storage node plugs.

When the support patterns are formed in parallel lines, the forming of the storage node holes may include: forming photoresist patterns disposed in parallel lines across the support patterns and etching the buried layer patterns and the molding layer using the photoresist patterns and the support patterns as an etching mask.

In accordance with an exemplary embodiment of the present invention, a semiconductor device is provided. The semiconductor device includes: support patterns disposed formed in parallel lines on a substrate, storage node electrodes formed on both sidewalls of the support patterns parallel to an extension direction of the support patterns and spaced at specific intervals in the extension direction, wherein the storage node electrodes are supported by the support patterns. The semiconductor device further includes a dielectric layer disposed on the storage node electrodes and a plate electrode disposed on the dielectric layer.

The semiconductor device may further include: an interlayer insulating layer disposed between the substrate and the storage node electrodes, lower conductive lines disposed in the interlayer insulating layer and storage node plugs disposed between the lower conductive lines in the interlayer insulating layer. Here, the support patterns may overlap the lower conductive lines, and the storage node electrodes may be formed on the storage node plugs. The lower conductive lines may be bit lines.

Upper ends of the storage node electrodes may be in contact with the sidewalls of the support patterns.

In accordance with another exemplary embodiment of the present invention, a semiconductor device is provided. The semiconductor device includes: support patterns formed along rows and columns on a substrate at crossings between odd-numbered rows and odd-numbered columns and between even-numbered rows and even-numbered columns, storage node electrodes disposed on both sidewalls of the support patterns and supported by the support patterns, a dielectric layer disposed on the storage node electrodes and a plate electrode disposed on the dielectric layer.

The semiconductor device may further include: an interlayer insulating layer disposed between the substrate and the storage node electrodes, bit lines disposed in the interlayer insulating layer; and storage node plugs disposed between the bit lines in the interlayer insulating layer. Here, each of the bit lines may alternately and repeatedly have a passing part and a contact part electrically connected with the substrate and having a larger width than the passing part. The passing parts of the bit lines may be formed to overlap the support patterns, and the storage node electrodes may be formed on the storage node plugs.

Upper ends of the storage node electrodes may be in contact with sidewalls of the support patterns.

### BRIEF DESCRIPTION OF THE DRAWINGS

Exemplary embodiments of the present invention can be understood in more detail from the following detailed description taken in conjunction with the accompanying drawings. It should be understood that various aspects of the drawings may have been exaggerated for clarity:

FIG. 1 is a plan view of a semiconductor device according to an exemplary embodiment of the present invention;

FIGS. 2A to 8A are cross-section views taken along line I-I′ of FIG. 1, illustrating a method of manufacturing a semiconductor device according to an exemplary embodiment of the present invention;

FIGS. 2B to 8B are cross-section views taken along line II-II′ of FIG. 1, illustrating the method of manufacturing a semiconductor device according to an exemplary embodiment of the present invention;

FIG. 9 is a plan view of a semiconductor device according to an exemplary embodiment of the present invention;

FIGS. 10A to 12A are cross-section views taken along line III-III′ of FIG. 9, illustrating a method of manufacturing a semiconductor device according to an exemplary embodiment of the present invention;

FIGS. 10B to 12B are cross-section views taken along line IV-IV′ of FIG. 9, illustrating the method of manufacturing a semiconductor device according to an exemplary embodiment of the present invention.

### DETAILED DESCRIPTION OF THE EXEMPLARY EMBODIMENTS OF THE INVENTION

Various exemplary embodiments of the present invention will now be described more fully with reference to the accompanying drawings in which some exemplary embodiments of the invention are shown. In the drawings, the thicknesses of layers and regions are exaggerated for clarity.

Detailed illustrative embodiments of the present invention are disclosed herein. However, specific structural and functional details disclosed herein are merely representative for purposes of describing exemplary embodiments of the present invention. This invention may, however, may be embodied in many alternate forms and should not be construed as limited to only the embodiments set forth herein.

Accordingly, while exemplary embodiments of the invention are capable of various modifications and alternative forms, embodiments thereof are shown by way of example in the drawings and will herein be described in detail. It should be understood, however, that there is no intent to limit exemplary embodiments of the invention to the particular forms disclosed, but on the contrary, exemplary embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of exemplary embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of exemplary embodiments of the invention. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

In this specification, the term “and/or” picks out each individual item as well as all combinations of them.

Terms used in this specification are intended not to limit the exemplary embodiments but to describe exemplary embodiments. Terms written in the singular are to be interpreted as possibly being plural unless stated otherwise. In addition, the terms “comprise” and/or “comprising” do not exclude the existence or addition of at least one component, step and/or device other than those mentioned.

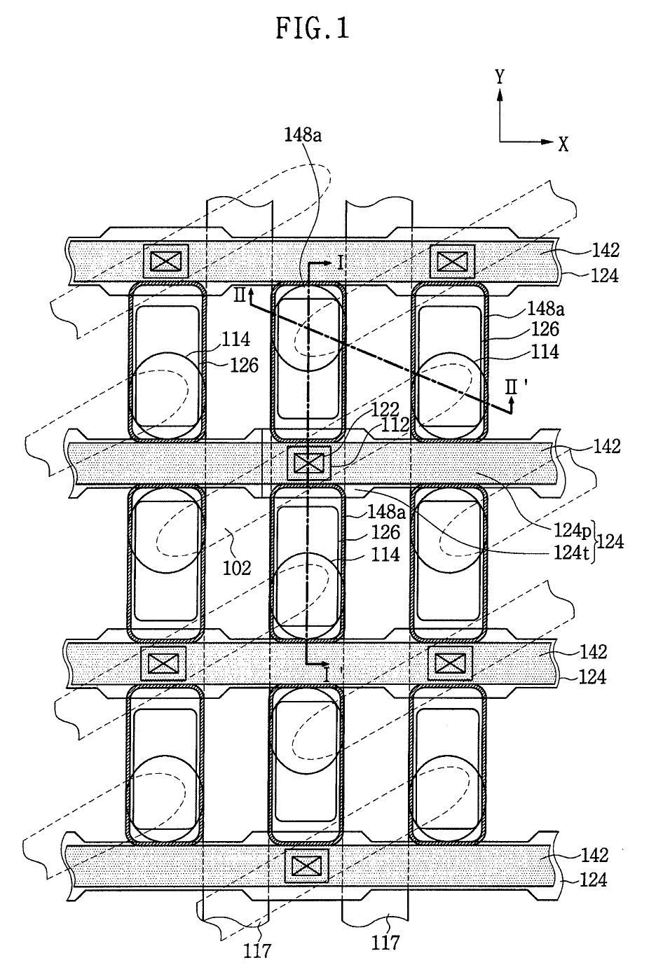

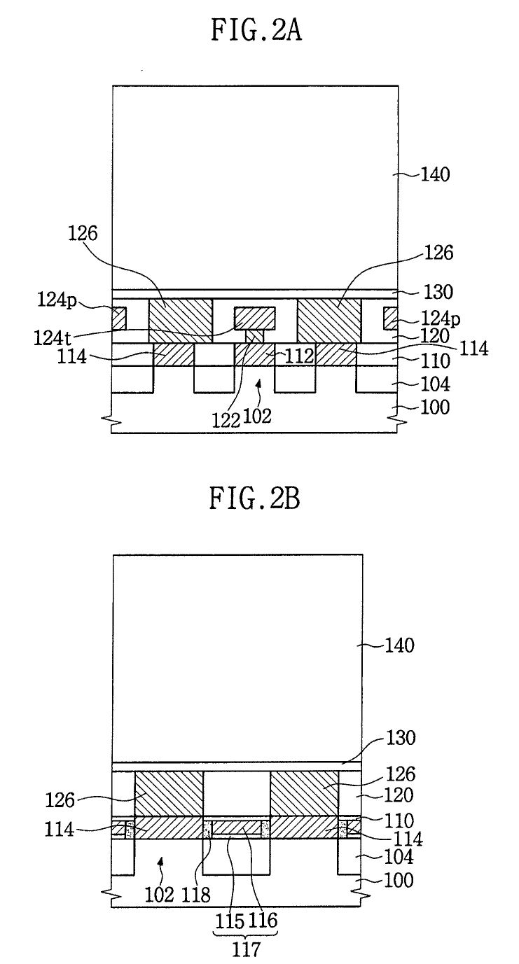

A method of manufacturing a semiconductor device according to a first exemplary embodiment of the present invention will be described in detail below with reference to FIGS. 1 to 8B. FIG. 1 is a plan view of a semiconductor device according to a first exemplary embodiment of the present invention. FIGS. 2A to 8A are cross-section views taken along line I-I′ of FIG. 1, illustrating a method of manufacturing the semiconductor device according to the first exemplary embodiment of the present invention. FIGS. 2B to 8B are cross-section views taken along line II-II′ of FIG. 1, illustrating the method of manufacturing the semiconductor device according to the first exemplary embodiment of the present invention.

Referring to FIGS. 1, 2A and 2B, an isolation region 104 may be formed in a substrate 100 to define active regions 102. For example, the substrate 100 may be a semiconductor substrate, which may be a single-crystal semiconductor substrate or a Silicon On Insulator (SOI) substrate having a single crystal semiconductor body layer. The single-crystal semiconductor substrate or the single-crystal semiconductor body layer may include, for example, a silicon layer, a germanium layer, a silicon germanium layer or so forth. The isolation region 104 may be formed using, for example, a trench isolation technique. The isolation region 104 may be formed of an insulating layer such as, for example, silicon oxide layer.

Gate patterns 117 may be formed on the substrate 100 having the active regions 102. As illustrated in FIG. 1, the gate patterns 117 may extend across the active regions 102 to constitute word lines. Each of the gate patterns 117 may be formed to have a gate insulating layer 115 and a gate electrode 116, which are sequentially stacked. The gate insulating layer 115 may be formed of, for example, a thermal oxide layer or a high-k dielectric layer. The gate electrode 116 may be formed of, for example, a doped silicon layer or a metal layer. Also, capping layer patterns including a silicon nitride layer may be further formed on the gate patterns 117. In addition, gate spacers 118 may be formed on sidewalls of the gate patterns 117. The gate spacers 118 may be formed of, for example, a silicon nitride layer. Moreover, impurity regions may be formed in the active regions 102 of both sides of the gate patterns 117.

A lower interlayer insulating layer 110 may be formed on the substrate 100 having the gate patterns 117. The lower interlayer insulating layer 110 may be formed of, for example, a silicon oxide layer. Landing pads 112 and 114 may be formed on the active regions 102 of the both sides of the gate patterns 117 through the lower interlayer insulating layer 110. For example, based on one of the active regions 102 shown in FIG. 1, the landing pads 112 and 114 may include a bit line landing pad 112 disposed on the active region 102 between the gate patterns 117, and storage landing pads 114 disposed at one side of the gate patterns 117, which is an opposite side of the bit line landing pad 112. The landing pads 112 and 114 may be formed through, for example, a self-alignment process using an etch selectivity between the gate spacers 118 and the lower interlayer insulating layer 110. The landing pads 112 and 114 may be formed of, for example, a doped polysilicon layer or a metal layer.

An upper interlayer insulating layer 120 having bit lines 124 crossing the word lines 117 may be formed on the lower interlayer insulating layer 110. The upper interlayer insulating layer 120 may be formed of substantially the same material layer as the lower interlayer insulating layer 110. The respective bit lines 124 may be electrically connected with the bit line landing pads 112 through bit line plugs 122 extending to the bit line landing pads 112. In this case, each of the bit lines 124 may be formed to alternately and repeatedly have a contact part 124t having a part connected with the bit line plug 122 and a passing part 124p not connected with the bit line plug 122. As illustrated in FIG. 2, the contact parts 124t may be designed to have a larger width than the passing parts 124p. This is intended to increase the area contacting the bit line plug 122 and ensure a process margin. Meanwhile, the bit lines 124 and the bit line plugs 122 may be formed of, for example, a doped silicon layer or a metal layer.

Storage node plugs 126 may be disposed between the bit lines 124 to penetrate the upper interlayer insulating layer 120 and spaced at specific intervals. In this case, the storage node plugs 126 may be formed on the storage landing pads 114 and electrically connected with the storage landing pads 114.

A molding layer 140 may be formed on the upper interlayer insulating layer 120 having the storage node plugs 126. The molding layer 140 may be formed of, for example, a silicon oxide layer, like the lower interlayer insulating layer 110. In addition, an etch-stop layer 130 may be formed between the molding layer 140 and the upper interlayer insulating layer 120. The etch-stop layer 130 may be, for example, a material layer having an etch selectivity with respect to the molding layer 140 and may be formed of a silicon nitride layer.

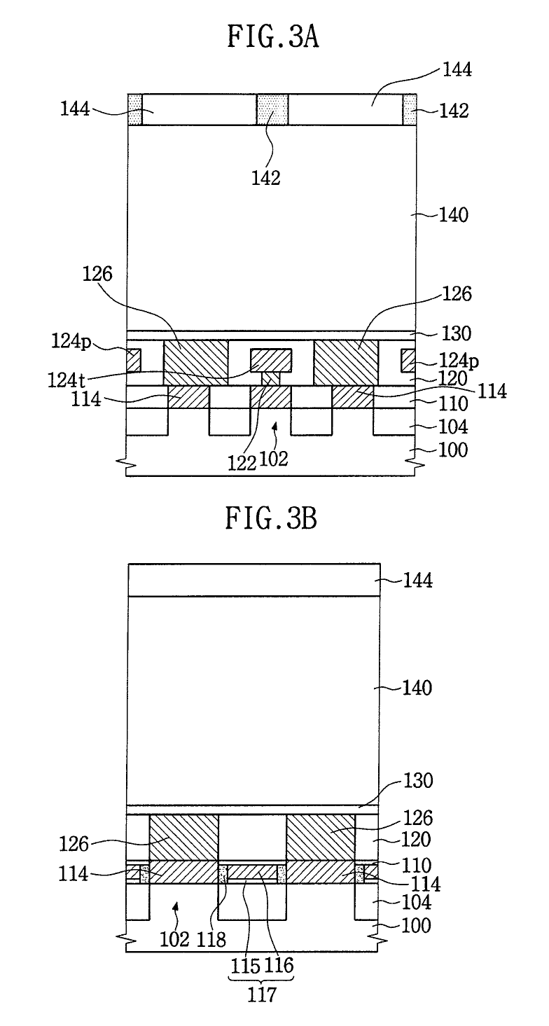

Referring to FIGS. 1, 3A and 3B, support patterns 142 may be formed spaced apart from each other on the molding layer 140. The support patterns 142 may be formed to overlap lower conductive lines such as the word lines 117 or the bit lines 124. In this example embodiment, the support patterns 142 may be spaced at specific intervals in a column direction Y, and may extend in a row direction X to overlap the bit lines 124. Therefore, the support patterns 142 may be formed to extend in the row direction X in parallel lines. In addition, the support patterns 142 may be formed to have substantially the same width as the passing parts 124p of the bit lines 124. Meanwhile, the support patterns 142 may be formed of a material layer, e.g., a silicon nitride layer, having an etch selectivity with respect to the molding layer 140.

A buried layer may be formed on the entire surface of the substrate 100 having the support patterns 142. The buried layer may be formed of the same material layer as the molding layer 140. A planarization process may be performed on the buried layer to expose the upper surfaces of the support patterns 142, so that buried layer patterns 144 can be formed between the support patterns 142 on the molding layer 140. In this exemplary embodiment, the buried layer patterns 144 are employed but may be omitted depending on the process.

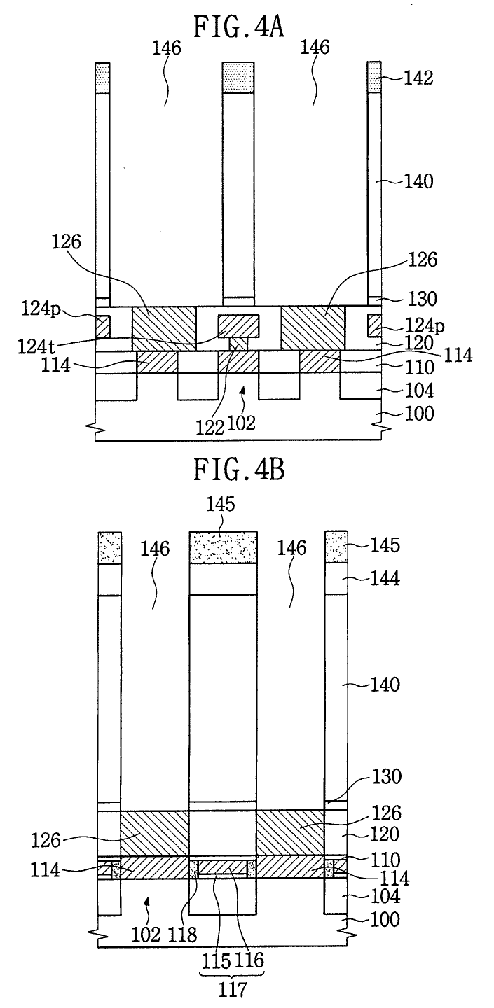

Referring to FIGS. 1, 4A and 4B, photoresist patterns 145 crossing the support patterns 142 may be formed in parallel lines on the support patterns 142 and the buried layer patterns 144. In this case, the photoresist patterns 145 may be formed to overlap the word lines 117. As a result, regions surrounded by the support patterns 142 and the photoresist patterns 145 may overlap the storage node plugs 126. In this case, a mask pattern having openings, which are formed by combining the support patterns 142 formed in lines with the photoresist patterns 145 formed in lines, may be readily formed in comparison with a photoresist pattern having holes.

Subsequently, the buried layer patterns 144 and the molding layer 140 may be etched using the support patterns 142 and the photoresist patterns 145 as an etching mask. The above-mentioned etching process may be performed to the etch-stop layer 130, and an additional etching process may be performed with respect to the etch-stop layer 130. As a result, storage node holes 146 exposing the storage node plugs 126 may be formed at the both sides of the support patterns 142. In this case, the respective storage node holes 146 between the support patterns 142 may be formed to be self-aligned perpendicular to the sidewalls of the support patterns 142 adjacent in the column direction Y. In addition, the storage node holes 146 between the support patterns 142 may be arranged in the extension direction of the support patterns 142, e.g., in the row direction X to be spaced at specific intervals. In this exemplary embodiment, the support patterns 142 may be used in the process of forming the storage node holes 146, and thus the respective storage node holes 146 do not expose the storage node plugs 126 adjacent to the corresponding storage node plugs 126. In other words, misalignment of the storage node holes 146 may be prevented, so that a process margin can be ensured.

Meanwhile, the storage node holes 146 may be arranged in various forms using a photoresist pattern having hole-shaped openings. For example, the storage node holes 146 between the neighboring support patterns 142 may be disposed to be spaced at specific intervals in the row direction X, as described above. However, the storage node holes 146 between the neighboring support patterns 142 are formed to be aligned with only one of the sidewalls of the support patterns 142 adjacent in the column direction Y. In this case, the storage node holes 146 between the neighboring support patterns 142 may be formed out of line to be aligned with the side walls of the different support patterns 142.

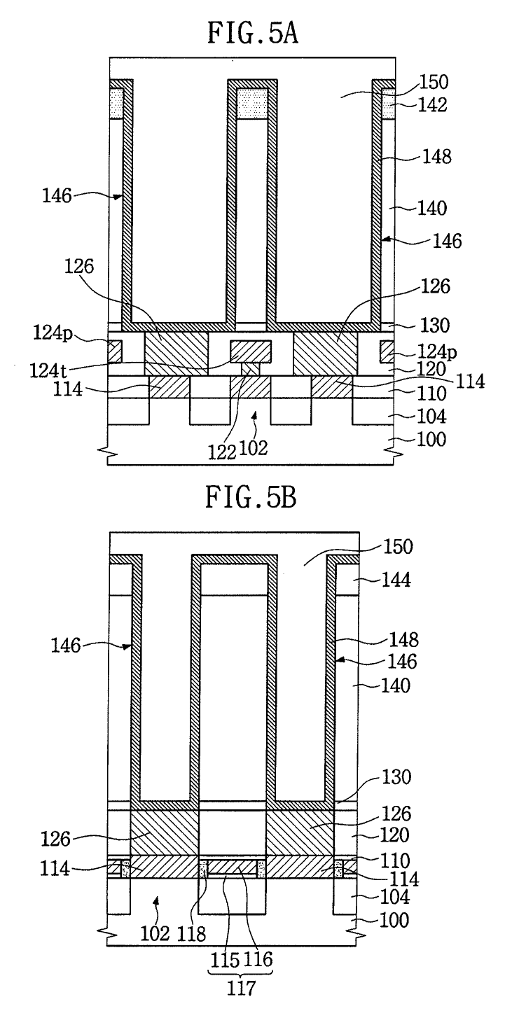

Referring to FIGS. 1, 5A and 5B, the photoresist patterns 145 may be removed, and then a storage node layer 148 may be formed to have a surface profile consistent with the substrate 100 having the storage node holes 146. For example, the storage node layer 148 may be a conductive layer and may be formed of a polysilicon layer doped with impurities or a metal layer. The storage node layer 148 may be formed to have, for example, a uniform thickness using low pressure chemical vapor deposition (LPCVD) or atomic layer deposition (ALD).

A sacrificial layer 150 may be formed on the storage node layer 148 to fill the storage node holes 146. The sacrificial layer 150 may be formed of the same material layer, e.g., a silicon oxide layer, as the molding layer 140.

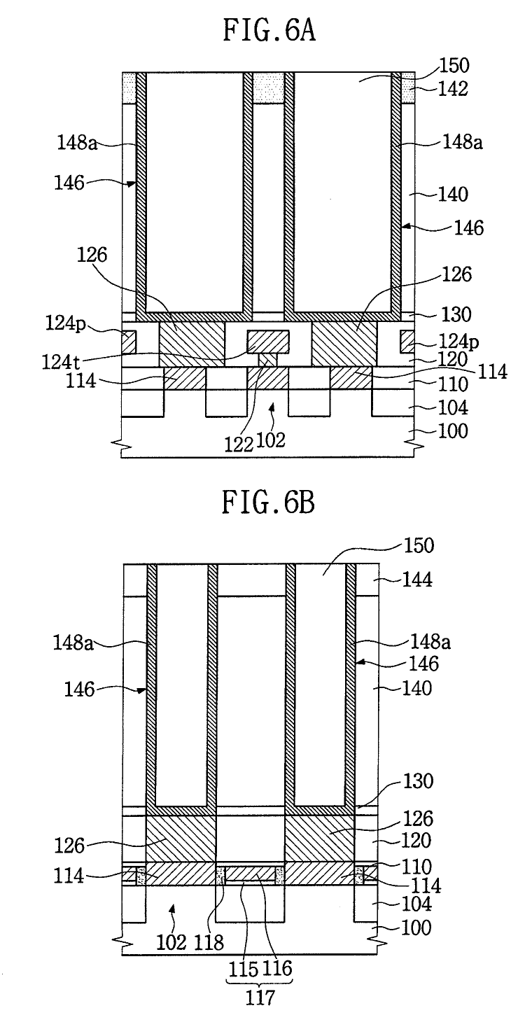

Referring to FIGS. 1, 6A and 6B, the sacrificial layer 150 and the storage node layer 148 may be planarized such that the upper surfaces of the support patterns 142 and the buried layer patterns 144 are exposed. The planarization may be performed using, for example, a chemical mechanical polishing (CMP) process or an etch-back process. As a result, the storage node layer 148 may remain in the respective storage node holes 146 and also on the sidewalls of the support patterns 142 formed at both sides of the storage node holes 146. In other words, storage node electrodes 148a may be formed by dividing the storage node layer 148. In addition, the sacrificial layer 150 may remain in the storage node electrodes 148a. In this case, based on one of the support patterns 142, the storage node electrodes 148a may be disposed on both sidewalls of the support pattern 142 parallel to the row direction X and may be spaced at specific intervals in the row direction X as illustrated in FIGS. 1 and 6A.

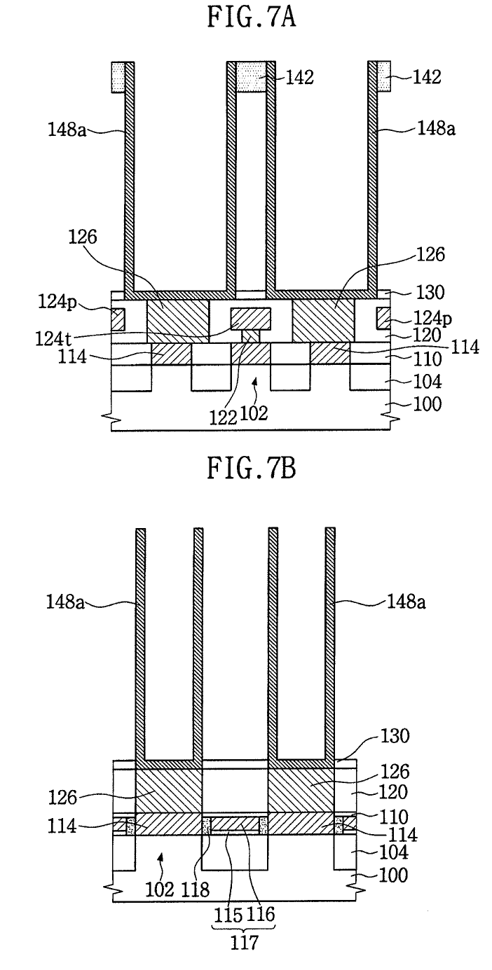

Referring to FIGS. 1, 7A and 7B, an isotropic etching process may be performed on the exposed buried layer patterns 144, the remaining sacrificial layer 150 and the molding layer 140. For example, the isotropic etching process may be a wet etching process using an etching solution or a chemical dry etching process using an etching gas. In the wet etching process, for example, an etching solution including hydrogen fluoride, an etching solution including ammonium hydroxide, hydrogen peroxide and deionized water, or a limulus amebocyte lysate (LAL) etching solution including ammonium fluoride, hydrogen fluoride and distilled water may be used. As a result, the support patterns 142 and the storage node electrodes 148a may be wholly exposed, and the support patterns 142 may support the adjacent storage node electrodes 148a. For example, the storage node electrodes 148a may be arranged at both sides of the line-shaped support patterns 142 and spaced at specific intervals in the row direction X. In this case, upper ends of the respective storage node electrodes 148a may be formed to be supported by the support patterns 142 in the column direction Y. Consequently, the storage node electrodes 148a may be prevented from leaning or deformation, and also a bridge between the adjacent storage node electrodes 148a may be prevented.

Meanwhile, in other exemplary embodiments, the storage node holes 146 may be arranged out of line between the neighboring support patterns 142 as described with reference to FIGS. 4A and 4B. In this case, the storage node electrodes 148a disposed between the neighboring support patterns 142 may fill the storage node holes 146 arranged out of line and thus may be formed on the sidewalls of the different support patters 142 out of line.

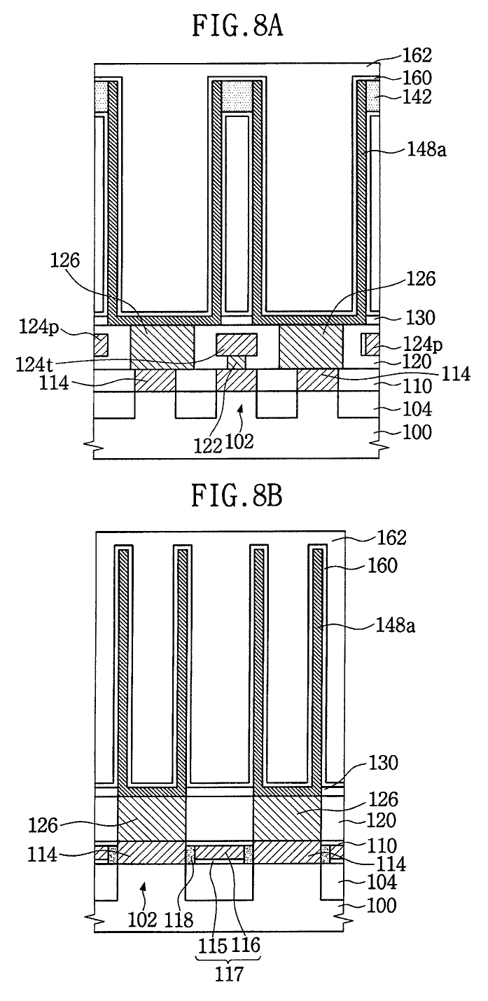

Referring to FIGS. 1, 8A and 8B, a dielectric layer 160 and a plate electrode 162 may be formed in sequence on the storage node electrodes 148a supported by the support patterns 142. The dielectric layer 160 and the plate electrode 162 may be formed on the entire surfaces of the storage node electrodes 148a and the support patterns 142. The dielectric layer 160 may be formed of, for example, a silicon oxide layer, a silicon nitride layer, a combination layer thereof or a high-k dielectric layer. The plate electrode 162 may be formed of, for example, a doped polysilicon layer or a metal layer.

In this exemplary embodiment, the storage node electrodes 148a have a cylinder shape. However, the storage node electrodes 148a are not limited to the shape but can be modified into various shapes. For example, the storage node electrodes 148a may be formed in a bar shape completely filling the storage node holes 146.

The structure of the semiconductor device according to the first exemplary embodiment of the present invention will be described below with reference to FIGS. 1, 8A and 8B.

The active regions 102 may be defined by an isolation region 104 in a substrate 100. For example, the substrate 100 may be a semiconductor substrate, which may be a single-crystal semiconductor substrate or an SOI substrate having a single crystal semiconductor body layer. The isolation region 104 may be formed of an insulating layer such as, for example, a silicon oxide layer.

Gate patterns 117 may be disposed on the substrate 100 having the active regions 102. As illustrated in FIG. 1, the gate patterns 117 may extend across the active regions 102 and thus may constitute word lines. Each of the gate patterns 117 may include a gate insulating layer 115 and a gate electrode 116, which are sequentially stacked. Also, capping layer patterns including, for example, a silicon nitride layer may be additionally disposed on the gate patterns 117. In addition, gate spacers 118 may be disposed on sidewalls of the gate patterns 117. Moreover, impurity regions may be provided in the active regions 102 at both sides of the gate patterns 117.

A lower interlayer insulating layer 110 may be disposed on the substrate 100 having the gate patterns 117. Landing pads 112 and 114 may be disposed on the active regions 102 at both sides of the gate patterns 117 through the lower interlayer insulating layer 110. For example, based on one of the active regions 102 shown in FIG. 1, the landing pads 112 and 114 may include a bit line landing pad 112 on the active region 102 disposed between the gate patterns 117, and storage landing pads 114 disposed at one side of the gate patterns 117, which is disposed at an opposite side of the bit line landing pad 112. The landing pads 112 and 114 may be formed of, for example, a doped polysilicon layer or a metal layer.

An upper interlayer insulating layer 120 may be disposed on the lower interlayer insulating layer 110, and bit lines 124 crossing the word lines 117 may be disposed in the upper interlayer insulating layer 120. The upper interlayer insulating layer 120 may be formed of substantially the same material layer as the lower interlayer insulating layer 110. The respective bit lines 124 may be electrically connected with the bit line landing pads 112 through the bit line plugs 122 extending to the bit line landing pads 112. In this case, each of the bit lines 124 may alternately and repeatedly include a contact part 124t having a part connected with the bit line plug 122 and a passing part 124p not connected with the bit line plug 122. As illustrated in FIG. 1, the contact parts 124t may be designed to have a larger width than the passing parts 124p. This is intended to increase an area contacting the bit line plug 122.

Storage node plugs 126 may be disposed between the bit lines 124 through the upper interlayer insulating layer 120 to be spaced at specific intervals. In this case, the storage node plugs 126 may be formed on the storage landing pads 114 and electrically connected with the storage landing pads 114. In addition, an etch-stop layer 130 may be formed on the upper interlayer insulating layer 120 having the storage node plugs 126.

The storage node electrodes 148a may be disposed on the storage node plugs 126 through the etch-stop layer 130. As illustrated in FIG. 2, the storage node electrodes 148a may be disposed between the bit lines 124 and spaced at specific intervals in the row direction X and between the word lines 117 and spaced apart at specific intervals in the column direction Y. For example, the storage node electrodes 148a may be conductive layers and may be formed of a polysilicon layer doped with impurities or a metal layer. The storage node electrodes 148a may be formed in a cylinder shape. The storage node electrodes 148a are not limited to the shape shown in the drawings but may have various shapes. For example, the storage node electrodes 148a may be formed in a bar shape.

Support patterns 142 may pass between upper ends of the storage node electrodes 148a and have parallel line shapes. As illustrated in FIGS. 1 and 8A, the upper ends of the storage node electrodes 148a may be formed directly on both sidewalls of the support patterns 142 parallel to the extension direction of the support patterns 142, that is, the row direction X. In addition, the storage node electrodes 148a between the neighboring support patterns 142 may be formed directly on the sidewalls of the support patterns 142 at both sides of the storage node electrodes 148a. Therefore, the adjacent storage node electrodes 148a may be supported by the support patterns 142.

Meanwhile, the support patterns 142 may be formed to overlap lower conductive lines between the storage node electrodes 148a, and the lower conductive lines may be the word lines 117 or the bit lines 124. In this exemplary embodiment, the support patterns 142 extend in the row direction X and are spaced at specific intervals in the column direction Y to overlap the bit lines 124. In addition, the support patterns 142 may be formed to have substantially the same width as the passing parts 124p of the bit lines 124. The support patterns 142 may be formed of an insulating layer such as, for example, a silicon nitride layer.

In this exemplary embodiment, the storage node electrodes 148a between the neighboring support patterns 142 are supported by the support patterns 142 disposed at both sides of the storage node electrodes 148a. In other exemplary embodiments, the storage node electrodes 148a between the neighboring support patterns 142 may be supported by one of the support patterns 142 disposed at both sides. In this case, the storage node electrodes 148a between the neighboring support patterns 142 may be arranged out of line to be supported by the different support patterns 142.

The dielectric layer 160 and the plate electrode 162 may be formed on the entire surfaces of the storage node electrodes 148a and the support patterns 142. The dielectric layer 160 may be formed of, for example, a silicon oxide layer, a silicon nitride layer, a combination layer thereof or a high-k dielectric layer. The plate electrode 162 may be formed of, for example, a doped polysilicon layer or a metal layer.

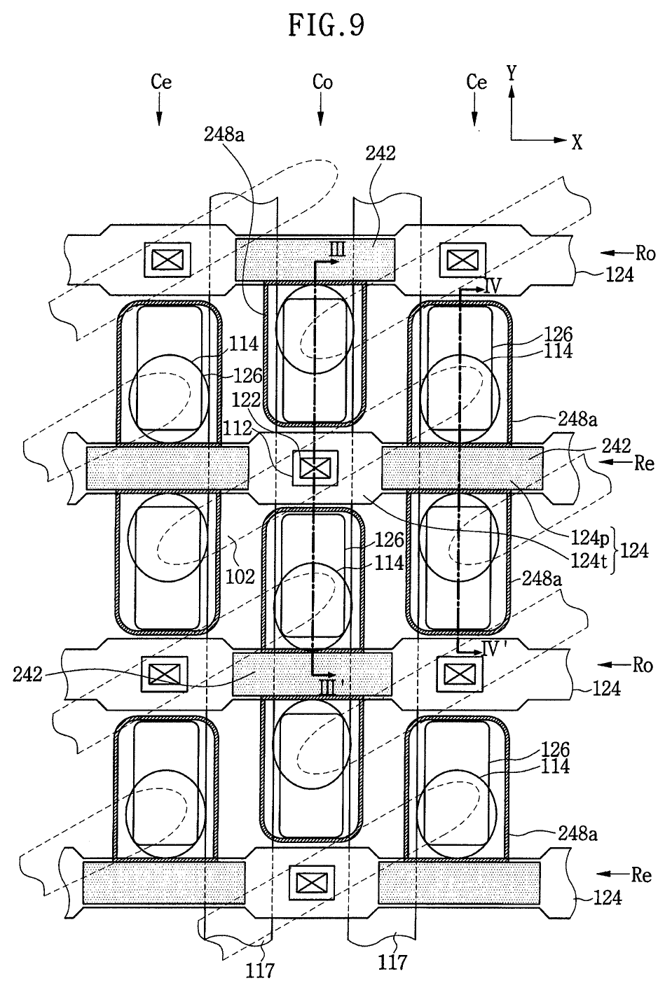

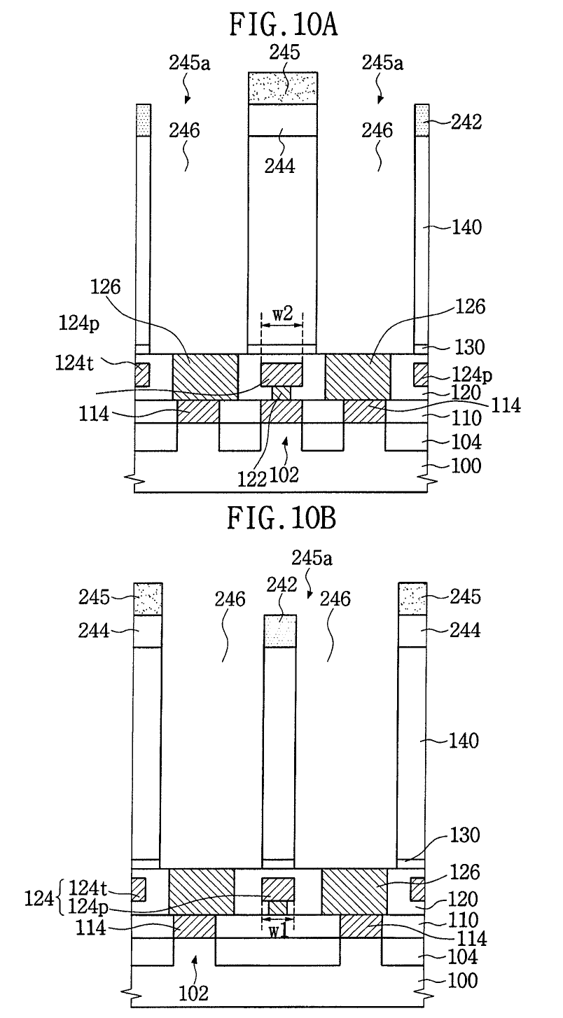

A method of manufacturing a semiconductor device according to a second exemplary embodiment will be described in detail below with reference to FIGS. 9 to 12B. FIG. 9 is a plan view of the semiconductor device according to the second exemplary embodiment of the present invention. FIGS. 10A to 12A are cross-section views taken along line III-III′ of FIG. 9, illustrating the method of manufacturing the semiconductor device according to the second exemplary embodiment of the present invention. FIGS. 10B to 12B are cross-section views taken along line IV-IV′ of FIG. 9, illustrating the method of manufacturing the semiconductor device according to the second exemplary embodiment of the present invention. The second exemplary embodiment to be described below has significant differences in the process of forming support patterns in comparison with the first exemplary embodiment described with reference to FIGS. 1 to 8B.

Referring to FIGS. 9, 10A and 10B, an isolation region 104 may be formed in a substrate 100 to define active regions 102. Gate patterns 117 may be formed on the substrate 100 having the active regions 102. As illustrated in FIG. 9, the gate patterns 117 may extend across the active regions 102 and thus may constitute word lines. Each of the gate patterns 117 may be formed to have a gate insulating layer 115 and a gate electrode 116, which are sequentially stacked. In addition, gate spacers 118 may be formed on sidewalls of the gate patterns 117. Also, impurity regions may be formed in the active regions 102 at both sides of the gate patterns 117.

A lower interlayer insulating layer 110 may be formed on the substrate 100 having the gate patterns 117. Landing pads 112 and 114 may be formed on the active regions 102 at both sides of the gate patterns 117 to penetrate the lower interlayer insulating layer 110. For example, on one of the active regions 102 shown in FIG. 9, the landing pads 112 and 114 may include a bit line landing pad 112 on the active region 102 disposed between the gate patterns 117, and storage landing pads 114 disposed on one side of the gate patterns 117, which is the opposite side of the bit line landing pad 112.

An upper interlayer insulating layer 120 having bit lines 124 crossing the word lines 117 may be formed on the lower interlayer insulating layer 110. The respective bit lines 124 may be electrically connected with the bit line landing pads 112 through bit line plugs 122 vertically extending to the bit line landing pads 112. In this case, each of the bit lines 124 may be formed to alternately and repeatedly have a contact part 124t having a part connected with the bit line plug 122 in a row direction X and a passing part 124p not connected with the bit line plug 122. The contact parts 124t may be designed to have a width W2 larger than a width W1 of the passing parts 124p to increase an area contacting the bit line plug 122 and ensure a process margin.

In addition, as illustrated in FIG. 9, the passing parts 124p formed in the neighboring bit lines 124 may be arranged out of line such that the contact parts 124t and the passing parts 124p disposed in a column direction Y can be alternately aligned. In FIG. 9, rows Ro and Re denote lines that are parallel to the row direction X and overlap the bit lines 124, and may be classified into odd-numbered rows Ro and even-numbered rows Re. Columns Co and Ce denote virtual lines that are parallel to the column direction Y and exist between the word lines 117, and may be classified into odd-numbered columns Co and even-numbered columns Ce. Thus, the passing parts 124p may be formed at crossings between the odd-numbered rows Ro and the odd-numbered columns Co and between the even-numbered rows Re and the even-numbered columns Ce. In association with this, the contact parts 124t may be formed at crossings between the odd-numbered rows Ro and the even-numbered columns Ce and between the even-numbered rows Re and the odd-numbered columns Co. In this case, the passing parts 124p are not disposed only at the crossings but also may extend to overlap parts of the word lines 117 at both sides to be connected with the contact parts 124t. Meanwhile, coordinates in this exemplary embodiment are intended to readily describe the arrangement of the passing parts 124p and do not denote absolute coordinates. Therefore, a reference for the odd-numbered rows and the odd-numbered columns may be randomly determined in FIG. 9.

Storage node plugs 126 may be disposed between the bit lines 124 through the upper interlayer insulating layer 120 to be spaced at specific intervals. In this case, the storage node plugs 126 may be formed between the contact parts 124t and the passing parts 124p neighboring each other in the column direction Y as illustrated in FIG. 9. Meanwhile, the storage node plugs 126 may be formed on the storage landing pads 114 and electrically connected with the storage landing pads 114.

A molding layer 140 may be formed on the upper interlayer insulating layer 120 having the storage node plugs 126. In addition, an etch-stop layer 130 may be additionally formed between the molding layer 140 and the upper interlayer insulating layer 120.

Processes and materials related to the above-described word lines 117, landing pads 112 and 114, bit lines 124, storage node plugs 126 and molding layer 140 are substantially the same as described in the first exemplary embodiment with reference to FIGS. 2A and 2B and thus another description of these elements will be omitted.

Support patterns 242 having an island shape may be formed on the molding layer 140 to overlap the passing parts 124p of the bit lines 124 and spaced apart from each other. The support patterns 242 may be formed of a material layer such as, for example, a silicon nitride layer having an etch selectivity with respect to the molding layer 140. Subsequently, buried layer patterns 244 may be formed on the molding layer 140 exposed between the support patterns 242. The buried layer patterns 244 may be formed of the same material layer as the molding layer 140.

A photoresist pattern 245 having openings 245a, which expose specific regions of the buried layer patterns 244 at both sides of the support patterns 242 and the support patterns 242 between the specific regions, may be formed. The specific regions of the buried layer patterns 244 may be formed to overlap the storage node plugs 126. The buried layer patterns 244 and the molding layer 140 may be etched in sequence using the exposed support patterns 242 and the photoresist pattern 245 as an etching mask. The above-mentioned etching process may be performed to the etch-stop layer 130, and an additional etching process may be performed on the etch-stop layer 130. As a result, storage node holes 246 exposing the storage node plugs 126 may be formed at the both sides of the support patterns 242. In this case, the respective storage node holes 246 at the both sides of the support patterns 242 may be aligned to both sidewalls of the support patterns 242.

In this exemplary embodiment, the support patterns 242 may be used in the process of forming the storage node holes 246, and thus the respective storage node holes 246 may not expose the storage node plugs 126 adjacent to the corresponding storage node plugs 126. In other words, misalignment of the storage node holes 246 may be prevented, so that a process margin can be ensured.

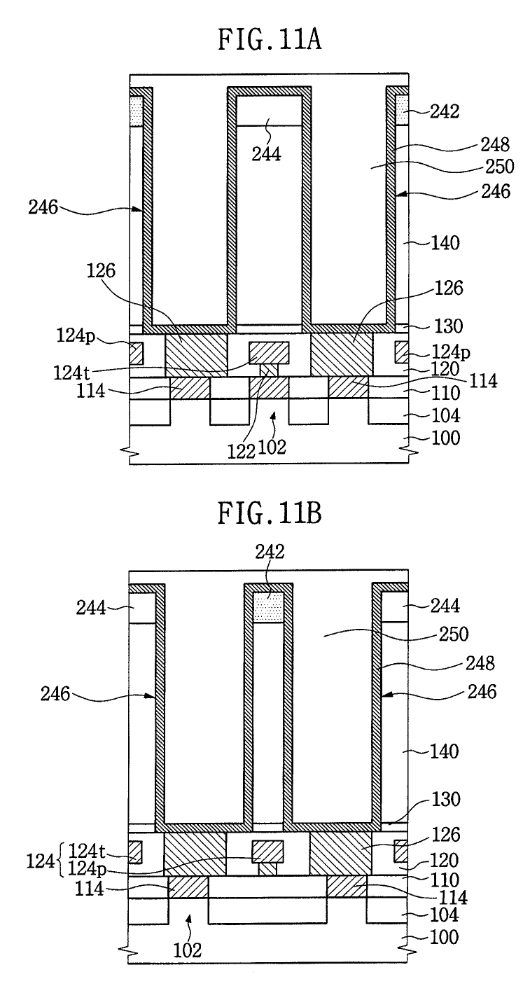

Referring to FIGS. 9, 11A and 11B, the photoresist pattern 245 may be removed, and then a storage node layer 248 may be formed to have a surface profile consistent with the substrate 100 having the storage node holes 246. Processes and materials related to the storage node layer 248 are substantially the same as described in the first example embodiment with reference to FIGS. 5A and 5B and thus another description of these elements will be omitted. Subsequently, a sacrificial layer 250 may be formed on the storage node layer 248 to fill the storage node holes 246. The sacrificial layer 250 may be formed of the same material layer, e.g., a silicon oxide layer, as the molding layer 140.

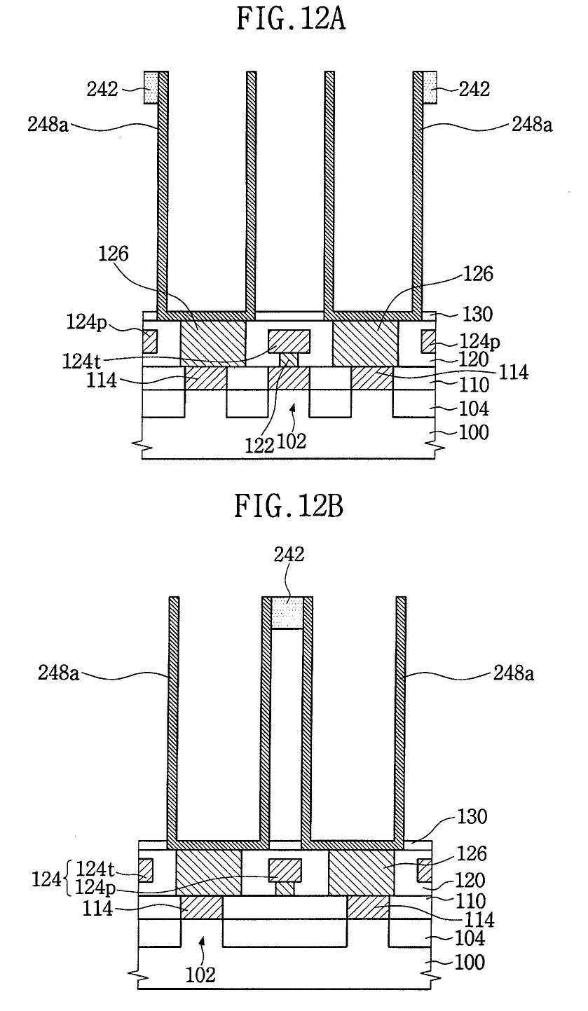

Referring to FIGS. 9, 12A and 12B, the sacrificial layer 250 and the storage node layer 248 may be planarized such that the upper surfaces of the support patterns 242 and the buried layer patterns 244 are exposed. As a result, the storage node layer 248 may remain in each of the storage node holes 246 and also on the sidewalls of the support patterns 242 disposed on one side of each of the storage node holes 246. In other words, storage node electrodes 248a may be formed by dividing the storage node layer 248. In addition, the sacrificial layer 250 may remain in the storage node electrodes 248a.

Subsequently, an isotropic etching process may be performed on the exposed buried layer patterns 244, the remaining sacrificial layer 250 and the molding layer 140. As the isotropic etching process is substantially the same as described in the first example embodiments with reference to FIGS. 7A and 7B, it will not be described again. As a result, the support patterns 242 and the storage node electrodes 248a are wholly exposed, and the support patterns 242 support the adjacent storage node electrodes 248a. For example, the storage node electrodes 248a may be arranged at both sides of the support patterns 242 spaced apart from each other, and upper ends of each of the storage node electrodes 248a are in contact with the both sidewalls of the support patterns 242 and the storage node electrodes 248a are supported by the support patterns 242. Consequently, the storage node electrodes 248a are prevented from leaning or deformation, and also a bridge between the adjacent storage node electrodes 248a may be prevented.

The semiconductor device according to the second exemplary embodiment of the present invention will be described below with reference to FIGS. 9, 12A and 12B. The second exemplary embodiment to be described below has significant differences in the shape of support patterns in comparison with the first exemplary embodiment described with reference to FIGS. 1, 8A and 8B.

The active regions 102 may be defined by an isolation region 104 in a substrate 100. Gate patterns 117 may be disposed on the substrate 100 having the active regions 102. As illustrated in FIG. 9, the gate patterns 117 may extend across the active regions 102 and thus may constitute word lines. Each of the gate patterns 117 may have a gate insulating layer 115 and a gate electrode 116, which are sequentially stacked. Capping layer patterns including a silicon nitride layer may be additionally disposed on the gate patterns 117. In addition, gate spacers 118 may be disposed on sidewalls of the gate patterns 117. Additionally, impurity regions may be disposed in the active regions 102 at both sides of the gate patterns 117.

A lower interlayer insulating layer 110 may be disposed on the substrate 100 having the gate patterns 117. Landing pads 112 and 114 may be disposed on the active regions 102 at both sides of the gate patterns 117 through the lower interlayer insulating layer 110. For example, based on one of the active regions 102 shown in FIG. 9, the landing pads 112 and 114 may include a bit line landing pad 112 disposed on the active region 102 disposed between the gate patterns 117, and storage landing pads 114 disposed at one side of the gate patterns 117, which is disposed at an opposite side of the bit line landing pad 112.

An upper interlayer insulating layer 120 having bit lines 124 crossing the word lines 117 may be disposed on the lower interlayer insulating layer 110. The respective bit lines 124 may be electrically connected with the bit line landing pads 112 through bit line plugs 122 vertically extending to the bit line landing pads 112. In this case, each of the bit lines 124 may alternately and repeatedly include a contact part 124t having a part connected with the bit line plug 122 in the row direction X and a passing part 124p not connected with the bit line plug 122. To increase an area contacting the bit line plug 122, the contact parts 124t may be designed to have a larger width W2 than a width W1 of the passing parts 124p, as illustrated in FIG. 9.

In addition, as illustrated in FIG. 9, the passing parts 124p formed in the different bit lines 124 neighboring in the column direction Y may be arranged out of line. For example, the passing parts 124p may be formed to be arranged at crossings between the odd-numbered rows Ro and the odd-numbered columns Co and between the even-numbered rows Re and the even-numbered columns Ce. In association with this, the contact parts 124t may be formed to be arranged at crossings between the odd-numbered rows Ro and the even-numbered columns Ce and between the even-numbered rows Re and the odd-numbered columns Co. In this case, the passing parts 124p are not disposed only at the crossings but also extend to overlap parts of the word lines 117 at both sides. The even and odd-numbered rows Ro and Re and the even and odd-numbered columns Co and Ce have been described together with the method of fabricating the structure according to the second exemplary embodiment with reference to FIGS. 10A and 10B, and thus these elements will not be described again. Meanwhile, coordinates in this exemplary embodiment are intended to readily describe the arrangement of the passing parts 124p and do not denote absolute coordinates. Therefore, a reference for the odd-numbered rows and the odd-numbered columns may be randomly determined in FIG. 9.

Storage node plugs 126 may be disposed between the bit lines 124 through the upper interlayer insulating layer 120. In this case, the storage node plugs 126 may be disposed between the contact parts 124t and the passing parts 124p neighboring each other in the column direction Y as illustrated in FIG. 9. Meanwhile, the storage node plugs 126 may be formed on the storage landing pads 114 and electrically connected with the storage landing pads 114. In addition, an etch-stop layer 130 may be additionally formed on the upper interlayer insulating layer 120 having the storage node plugs 126. Support patterns 242 may be disposed on the etch-stop layer 130 and spaced apart from each other, and arranged to overlap the passing parts 124p of the bit lines 124. In this case, the support patterns 242 may be formed in an island shape.

Meanwhile, storage node electrodes 248a may be disposed on the storage node plugs 126 through the etch-stop layer 130. As illustrated in FIG. 9, the storage node electrodes 248a may be disposed between the bit lines 124 and spaced at specific intervals in the row direction X and between the word lines 117 and spaced at specific intervals in the column direction Y. In this case, upper ends of the storage node electrodes 248a may be arranged in contact with the both sidewalls of the respective support patterns 242. As a result, the storage node electrodes 248a may be connected and supported by the support patterns 242. In this exemplary embodiment, the storage node electrodes 248a may be formed in a cylinder shape. In other exemplary embodiments, the storage node electrodes 248a are not limited to the shape shown in the drawings but may have various shapes. For example, the storage node electrodes 248a may be formed in a bar shape.

Meanwhile, a dielectric layer and a plate electrode may be formed on the entire surfaces of the support patterns 242 and the storage node electrodes 248a, like the first exemplary embodiment of FIGS. 8A and 8B. As a result, capacitors are constituted by the storage node electrodes 248a, the dielectric layer and the plate electrode.

According to the exemplary embodiments of the present invention, support patterns are formed to connect the uppermost ends of storage node electrodes with each other, such that leaning of the storage node electrodes can be prevented. Meanwhile, the storage node electrodes are formed on storage node plugs while filling storage node holes, and thus can be electrically connected with the storage node plugs. In addition, lower conductive lines such as bit lines may be formed between the storage node plugs. In this case, the support patterns are formed to overlap the lower conductive lines. As a result, the support patterns are used as an etching mask when the storage node holes are formed, and thus the storage node holes may not expose the adjacent storage node plugs. In other words, the storage node holes may be self-aligned, such that misalignment can be prevented. Consequently, it is possible to improve reliability of a semiconductor device by applying the storage node electrodes supported by the support patterns to a semiconductor device.

Having described the exemplary embodiments of the present invention, it is further noted that it is readily apparent to those of reasonable skill in the art that various modifications may be made without departing from the spirit and scope of the invention which is defined by the metes and bounds of the appended claims.

1. A method of manufacturing a semiconductor device, comprising:
forming a molding layer on a substrate;
forming support patterns spaced apart from each other on the molding layer;
forming storage node electrodes penetrating the molding layer on both sidewalls of the support patterns and wherein the storage node electrodes are supported by the support patterns;
removing the molding layer;
forming a dielectric layer on the storage node electrodes; and
forming a plate electrode on the dielectric layer.

2. The method of claim 1, wherein the support patterns are formed in parallel lines, wherein the storage node electrodes are formed on the both sidewalls of the support patterns parallel to an extension direction of the support patterns and wherein the storage node electrodes are spaced at specific intervals in the extension direction.

3. The method of claim 2, wherein the storage node electrodes disposed between neighboring support patterns are formed on sidewalls of the neighboring support patterns.

4. The method of claim 1, wherein the support patterns are formed along rows and columns on the substrate at crossings between odd-numbered rows and odd-numbered columns and between even-numbered rows and even-numbered columns.

5. The method of claim 1, further comprising, before the forming of the molding layer:
forming an interlayer insulating layer having lower conductive lines on the substrate,
wherein the support patterns are formed to overlap the lower conductive lines.

6. The method of claim 5, wherein the lower conductive lines are bit lines each formed to alternately and repeatedly have a passing part and a contact part electrically connected with the substrate and having a larger width than the passing part, and each of the support patterns is formed to overlap the passing part.

7. The method of claim 1, wherein the support patterns are formed of a material layer having an etch selectivity with respect to the molding layer.

8. The method of claim 7, wherein the molding layer is formed of a silicon oxide layer, and the support patterns are formed of a silicon nitride layer.

9. The method of claim 1, wherein the forming of the storage node electrodes includes:
forming buried layer patterns on the molding layer exposed between the support patterns;
patterning the buried layer patterns and the molding layer, and forming storage node holes to expose both sidewalls of the support patterns;
forming a storage node layer to have a surface profile consistent with the substrate having the storage node holes;
removing the storage node layer on upper surfaces of the buried layer patterns and the support patterns; and
forming the storage node electrodes on the sidewalls of the support patterns.

10. The method of claim 9, wherein the buried layer patterns are formed of the same material layer as the molding layer, and wherein the buried layer patterns are removed while removing the molding layer.

11. The method of claim 9, further comprising, before the forming of the molding layer:
forming storage node plugs between the substrate and the molding layer, and
wherein the storage node holes are formed to expose the storage node plugs.

12. The method of claim 9, wherein the support patterns are formed in parallel lines, and wherein the forming of the storage node holes includes:
forming photoresist patterns disposed in parallel lines across the support patterns; and
etching the buried layer patterns and the molding layer using the photoresist patterns and the support patterns as an etching mask.

13-20. (canceled)
